(19) United States
(12) Patent Application Publication
(10) Pub. No.: US 2026/0082943 A1
(43) Pub. Date: Mar. 19, 2026

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventors: Daisuke Kajiyama, Himeji Hyogo (JP); Hajime Takagi, Himeji Hyogo (JP)

(21) Appl. No.: 19/240,649

(22) Filed: Jun. 17, 2025

(30) Foreign Application Priority Data
Sep. 19, 2024 (JP) 2024-162649

(51) Int. Cl. H01L 23/495; H01L 23/00; H01L 23/31

(52) U.S. Cl. CPC H10W 70/481; H10W 74/129; H10W 72/886; H10W 90/736; H10W 90/766

(57) ABSTRACT

A semiconductor chip includes a first electrode provided farther in a first direction than the first lead frame and is electrically coupled to a first lead frame, and a second electrode. A first conductor electrically coupled to the second electrode. A second lead frame is aligned with the first lead frame at a position farther in a second direction than the first lead frame and includes a first terminal and a plate portion connected to the first terminal. The plate portion is electrically coupled to the first conductor and has an inclination over a first surface on a side in the first direction and a first side surface on a side in the second direction. A resin covers a part of the first lead frame, the semiconductor chip, the first conductor, and the plate portion and a part of the first terminal.

### CROSS-REFERENCE TO RELATED APPLICATION

This application is based upon and claims the benefit of priority from Japanese Patent Application No. 2024-162649, filed Sep. 19, 2024, the entire contents of which are incorporated herein by reference.

### FIELD

Embodiments described herein relate generally to a semiconductor device.

### BACKGROUND

Examples of the semiconductor device include a device having a semiconductor chip, a package, and a connector. The semiconductor chip includes a semiconductor element such as a metal oxide semiconductor field effect transistor (MOSFET). The package covers the semiconductor chip and the connector. The connector is coupled to an electrode of the semiconductor chip via a conductor, and is partially exposed from the package.

### BRIEF DESCRIPTION OF THE DRAWINGS

FIG. 1 illustrates an appearance of a structure of a semiconductor device according to a first embodiment.

FIG. 2 illustrates an internal structure of the semiconductor device of the first embodiment along an xy plane.

FIG. 3 illustrates an internal structure of the semiconductor device of the first embodiment along an xy plane.

FIG. 4 illustrates a cross-sectional structure of the semiconductor device of the first embodiment.

FIG. 5 illustrates a cross-sectional structure of the semiconductor device of the first embodiment.

FIG. 6 illustrates a cross-sectional structure of the semiconductor device of the first embodiment.

FIG. 7 illustrates a partial structure of the semiconductor device of the first embodiment along an xy plane.

FIG. 8 illustrates a cross-sectional structure of the semiconductor device of the first embodiment.

FIG. 9 illustrates one state during manufacturing of the semiconductor device of the first embodiment.

FIG. 10 illustrates a state during manufacturing of a part of the semiconductor device of the first embodiment.

FIG. 11 illustrates an internal structure of a semiconductor device according to a modification of the first embodiment along an xy plane.

FIG. 12 illustrates a cross-sectional structure of a semiconductor device according to a modification of the first embodiment.

FIG. 13 illustrates a cross-sectional structure of a semiconductor device according to a modification of the first embodiment.

FIG. 14 illustrates a cross-sectional structure of a semiconductor device according to a modification of the first embodiment.

### DETAILED DESCRIPTION

In general, according to one embodiment, a semiconductor device includes a first lead frame, a semiconductor chip, a first conductor, a second lead frame, and a resin. The semiconductor chip includes a first electrode provided farther in a first direction than the first lead frame and electrically coupled to the first lead frame, and a second electrode. The first conductor is electrically coupled to the second electrode. The second lead frame is aligned with the first lead frame at a position farther in a second direction than the first lead frame and includes a first terminal and a plate portion connected to the first terminal. The plate portion is electrically coupled to the first conductor and has an inclination over a first surface on a side in the first direction and a first side surface on a side in the second direction. The resin covers a part of the first lead frame, the semiconductor chip, the first conductor, the plate portion of the second lead frame, and a part of the first terminal of the second lead frame.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a component and the ratio between dimensions of components may differ from those in actuality. The figures may include components which differ in relations, arrangement, and/or ratios of dimensions in different figures.

Hereinafter, embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a-Z direction.

### 1. First Embodiment

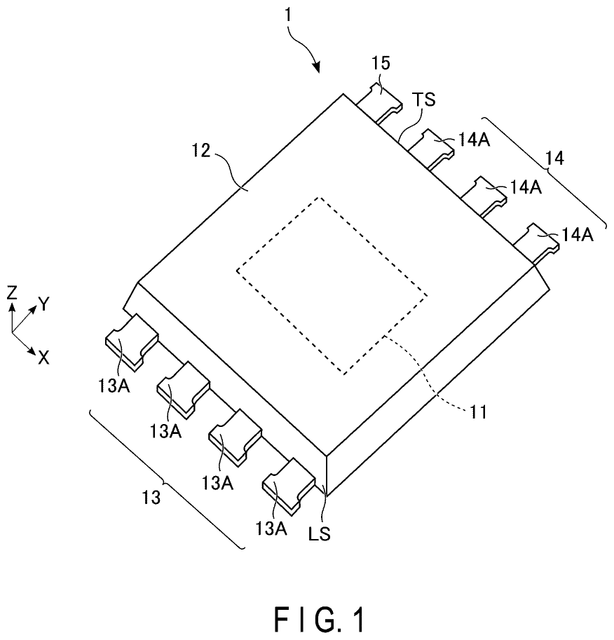

FIG. 1 illustrates an appearance of a structure of a semiconductor device according to a first embodiment. The semiconductor device 1 is configured as a semiconductor module constituting a part of another device.

As illustrated in FIG. 1, the semiconductor device 1 includes a semiconductor chip 11, a package 12, and lead frames (or external connection terminal) 13, 14, and 15.

The semiconductor chip 11 is a chip including a semiconductor element. Examples of the semiconductor element include an n-type MOSFET and an insulated gate bipolar transistor (IGBT). The following description is based on an example of a MOSFET.

The package 12 is a component that covers the internal structure of the semiconductor device 1 and covers the semiconductor chip 11 and a part of the lead frame 13. An example of a material of the package 12 includes an epoxy resin. Examples of the shape of the package 12 include a hexahedron, and examples of the hexahedron include a quadrangular prism and a rectangular parallelepiped. The following description is based on an example in which the package 12 has a shape of quadrangular prism. That is, the package 12 has an upper surface, a lower surface, and four side surfaces. The upper surface and the lower surface extend along the xy plane and face each other. The upper surface is positioned farther in the Z direction than the lower surface. The contour along the xy plane of the lower surface extends along the contour along the xy plane of the upper surface. In one example, the area of the lower surface along the xy plane is larger than the area of the upper surface along the xy plane. Each of the four side surfaces is connected to one side of the upper surface and one side of the lower surface, and has an inclination with respect to the z axis. The side surface includes a side surface LS and a side surface TS. The side surfaces LS and TS extend along the xz plane. The side surface LS and the side surface TS face each other. The side surface TS is positioned farther in the Y direction than the side surface LS.

The lead frame 13 is a conductor that electrically couples the semiconductor device 1 to a conductor outside the semiconductor device 1. The lead frame 13 is electrically coupled to the semiconductor chip 11. The lead frame 13 is partially exposed from the package 12 on the side surface LS. The lead frame 13 includes a plurality of first portions (external terminals) 13A exposed from the package 12 on the side surface LS. The first portions 13A are connected to each other in the package 12. The first portions 13A are arranged at intervals in the X direction.

The lead frame 14 is a conductor that electrically couples the semiconductor device 1 to a conductor outside the semiconductor device 1. The lead frame 14 is electrically coupled to the semiconductor chip 11. The lead frame 14 is partially exposed from the package 12 on the side surface TS. The lead frame 14 includes a plurality of first portions (external terminals) 14A exposed from the package 12 on the side surface TS. The first portions 14A are connected to each other in the package 12. The first portions 14A are arranged at intervals in the X direction.

The lead frame 15 is partially exposed from the package 12 on the side surface TS. The lead frame 15 is aligned with the first portion 14A.

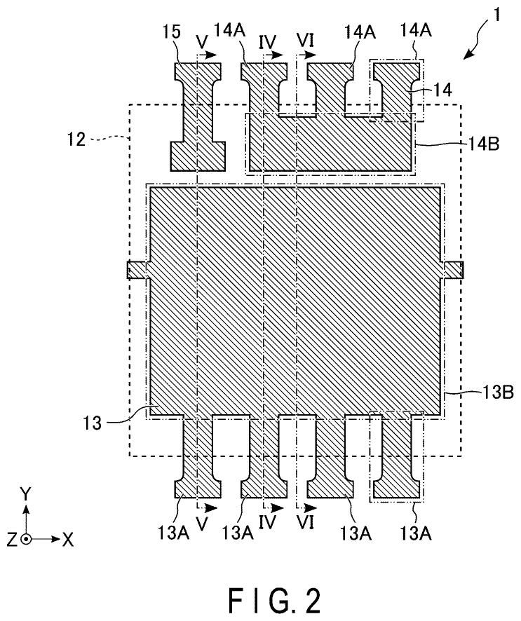

FIG. 2 illustrates an internal structure of the semiconductor device of the first embodiment along an xy plane. FIG. 2 illustrates a structure in a case where the semiconductor device 1 is viewed from the Z direction.

As illustrated in FIG. 2, the lead frame 13 extends along the xy plane. The lead frame 13 further includes a second portion (first plate portion) 13B. In one example, the second portion 13B has a quadrilateral shape. The second portion 13B may have protruding portions extending in the X direction and the-X direction. The second portion 13B is connected to the side of the first portion 13A on the Y direction side at the side on the-Y direction side. The first portion 13A extends in the Y direction.

The lead frame 14 extends along the xy plane. The lead frame 14 is positioned farther in the Y direction than the lead frame 13. The lead frame 14 is arranged with a space from the lead frame 13. The lead frame 14 further includes a second portion 14B. In one example, the second portion 14B has a quadrilateral shape. The second portion 14B is connected to the side of the first portion 14A on the-Y direction side at the side on the Y direction side. The first portion 14A extends in the Y direction.

The lead frame 15 extends along the xy plane. The lead frame 15 is positioned farther in the Y direction than the lead frame 13. The lead frame 15 is positioned farther in the-X direction than the lead frame 14. The lead frame 15 is arranged with a space from the lead frame 13 and the lead frame 14. The lead frame 15 extends in the Y direction.

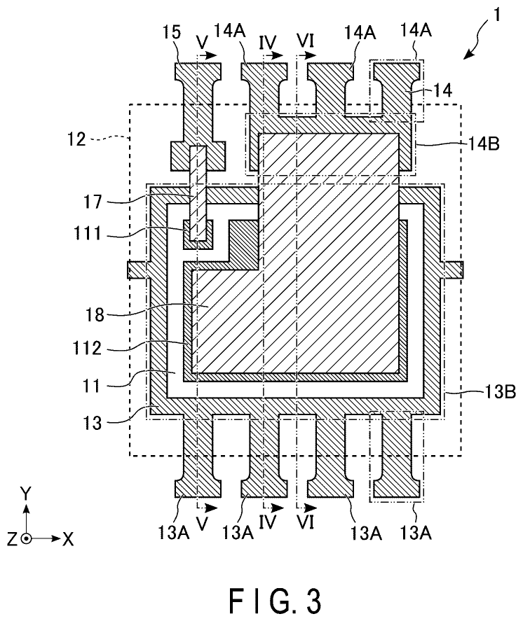

FIG. 3 illustrates an internal structure of the semiconductor device of the first embodiment along an xy plane. FIG. 3 illustrates a structure in a case where the semiconductor device 1 is viewed from the Z direction.

FIG. 3 illustrates a region positioned farther in the Z direction than the region illustrated in FIG. 2. As illustrated in FIG. 3, the semiconductor device 1 further includes conductors 17 and 18. The conductors 17 and 18 may also be referred to as connectors 17 and 18, respectively.

The semiconductor chip 11 extends along the xy plane. In one example, the semiconductor chip 11 has a quadrilateral shape. The semiconductor chip 11 overlaps the second portion 13B of the lead frame 13. In one example, the contour of the semiconductor chip 11 is positioned inside the contour of the second portion 13B of the lead frame 13. The semiconductor chip 11 is electrically coupled to the second portion 13B of the lead frame 13 at a drain electrode 113 to be described later.

The semiconductor chip 11 includes a gate electrode 111 and a source electrode 112. The gate electrode 111 is exposed on the upper surface (that is, the surface on the +Z direction side) of the semiconductor chip 11. The gate electrode 111 extends along the xy plane. In one example, the gate electrode 111 faces one side of the semiconductor chip 11. In one example, the gate electrode 111 faces the upper side (that is, the side on the Y direction side) of the semiconductor chip 11 and faces the left side (that is, the side on the −X direction side) of the semiconductor chip 11. The gate electrode 111 is coupled to a gate of a MOSFET or an IGBT in the semiconductor chip 11.

The source electrode 112 is exposed on the upper surface of the semiconductor chip 11. The source electrode 112 extends along the xy plane. The source electrode 112 extends over a region other than the region where the gate electrode 111 is exposed on the upper surface of the semiconductor chip 11. The source electrode 112 is spaced apart from the gate electrode 111. The source electrode 112 may have any shape as long as it extends over a region other than the region of the gate electrode 111 in the vicinity of the gate electrode 111. In one example, the source electrode 112 has a quadrilateral shape generally along the shape of the semiconductor chip 11, and has a quadrilateral notch around the gate electrode 111. The notch may have a shape in which a plurality of quadrilaterals are connected. The source electrode 112 is coupled to one end (or source) of the MOSFET. In a case where the semiconductor chip 11 includes an IGBT, the source electrode 112 is an emitter electrode and is coupled to an emitter of the IGBT.

The conductor 17 overlaps the gate electrode 111 and the lead frame 15.

The conductor 18 overlaps the source electrode 112 and the second portion 14B of the lead frame 14.

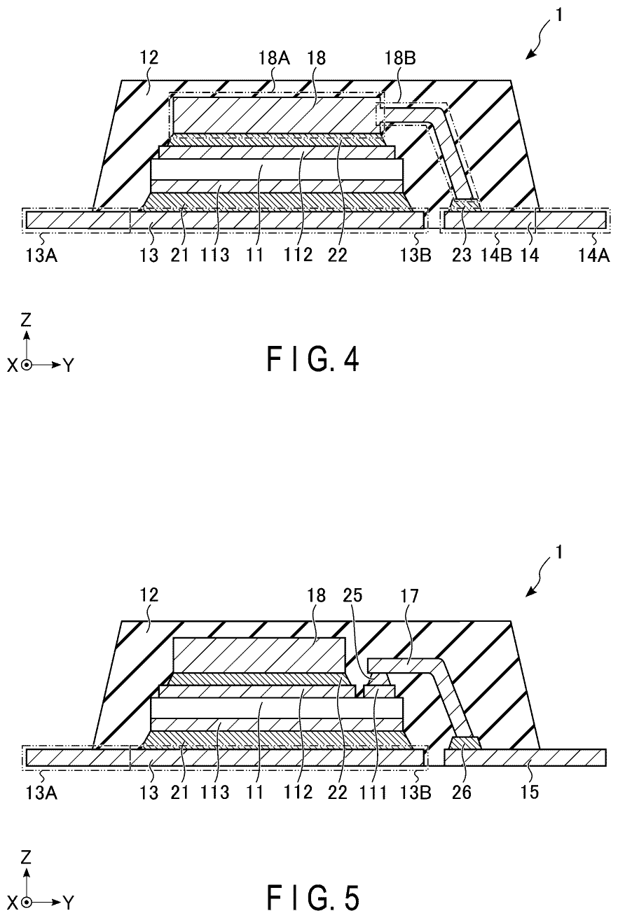

FIG. 4 illustrates a cross-sectional structure of the semiconductor device of the first embodiment. FIG. 4 illustrates a cross section taken along line IV-IV in FIGS. 2 and 3. As illustrated in FIG. 4, the semiconductor device 1 further includes bonding layers 21, 22, and 23.

The semiconductor chip 11 is positioned farther in the Z direction than the second portion 13B of the lead frame 13. The semiconductor chip 11 includes a drain electrode 113 on a surface (lower surface) on the −Z direction side. The drain electrode 113 extends along the xy plane. The semiconductor chip 11 includes a source electrode 112 on a surface (upper surface) on the Z direction side.

The bonding layer 21 is a layer having conductivity and including a conductor. The bonding layer 21 extends along the xy plane. In one example, the bonding layer 21 has a shape along the xy plane of the drain electrode 113 or the same shape as the drain electrode 113 along the xy plane. The bonding layer 21 is in contact with the second portion 13B and the drain electrode 113. The bonding layer 21 fixes and electrically couples the second portion 13B and the drain electrode 113. In one example, the bonding layer 21 includes solder.

The bonding layer 22 is a layer having conductivity and including a conductor. The bonding layer 22 extends along the xy plane. In one example, the bonding layer 22 has a shape along the xy plane of the source electrode 112 or the same shape as the source electrode 112 along the xy plane. The bonding layer 22 is in contact with the source electrode 112 and the conductor 18. The bonding layer 22 fixes and electrically couples the source electrode 112 and the conductor 18. In one example, the bonding layer 22 includes solder.

The conductor 18 has a first portion (first plate portion) 18A and a second portion (second plate portion) 18B. The first portion 18A and the second portion 18B are connected. The first portion 18A is positioned farther in the Z direction than the semiconductor chip 11. The conductor 18 is in contact with the bonding layer 22 in the first portion 18A. The second portion 18B extends in the Y direction and extends in the −Z direction from the level of the first portion 18A. An end of the second portion 18B opposite to the first portion 18A is positioned farther in the Z direction than the lead frame 14.

The bonding layer 23 is a layer having conductivity and including a conductor. The bonding layer 23 extends along the xy plane. In one example, the bonding layer 23 has a shape along the xy plane of the second portion 14B of the lead frame 14 or the same shape as the second portion 14B along the xy plane. The bonding layer 23 is in contact with the second portion 18B and the second portion 14B of the lead frame 14. The bonding layer 23 fixes and electrically couples the second portion 18B and the second portion 14B. In one example, the bonding layer 23 includes solder.

The package 12 covers the semiconductor chip 11, the bonding layers 21, 22, and 23, and the conductor 18. The package 12 covers a part of the upper surface of the lead frame 13. The package 12 covers a part of the upper surface of the lead frame 14.

As described above with reference to FIG. 4, the first portion (or terminal) 14A of the lead frame 14 is connected to each other by the second portion (or plate portion) 14B. Therefore, the area of the lead frame 14 is large, and eventually, the area where the lead frame 14 and the conductor 18 are in contact with each other via the bonding layer 23 is large. That is, it is conceivable that the plurality of first portions 14A independent from each other are electrically coupled to the source electrode 112 by a plurality of conductors independent from each other, but the lead frame 14 and the conductor 18 can be in contact with each other over a large area as compared with this case. This allows a large current to flow through the source.

FIG. 5 illustrates a cross-sectional structure of the semiconductor device of the first embodiment. FIG. 5 illustrates a cross section taken along line V-V in FIGS. 2 and 3. As illustrated in FIG. 5, the semiconductor device 1 further includes bonding layers 25 and 26.

The semiconductor chip 11 includes the gate electrode 111 on the upper surface.

The bonding layer 25 is a layer having conductivity and including a conductor. The bonding layer 25 is in contact with the gate electrode 111 and the conductor 17 (plate portion, wire). The bonding layer 25 fixes and electrically connects the gate electrode 111 and the conductor 17. In one example, the bonding layer 25 includes solder.

The conductor 17 extends in the-Z direction from the level positioned farther in the Z direction than the semiconductor chip 11. An end of the conductor 17 is positioned farther in the Z direction than the lead frame 15.

The bonding layer 26 is a layer having conductivity and including a conductor. The bonding layer 26 is in contact with the conductor 17 and the lead frame 15. The bonding layer 26 fixes and electrically couples the conductor 17 and the lead frame 15. In one example, the bonding layer 26 includes solder.

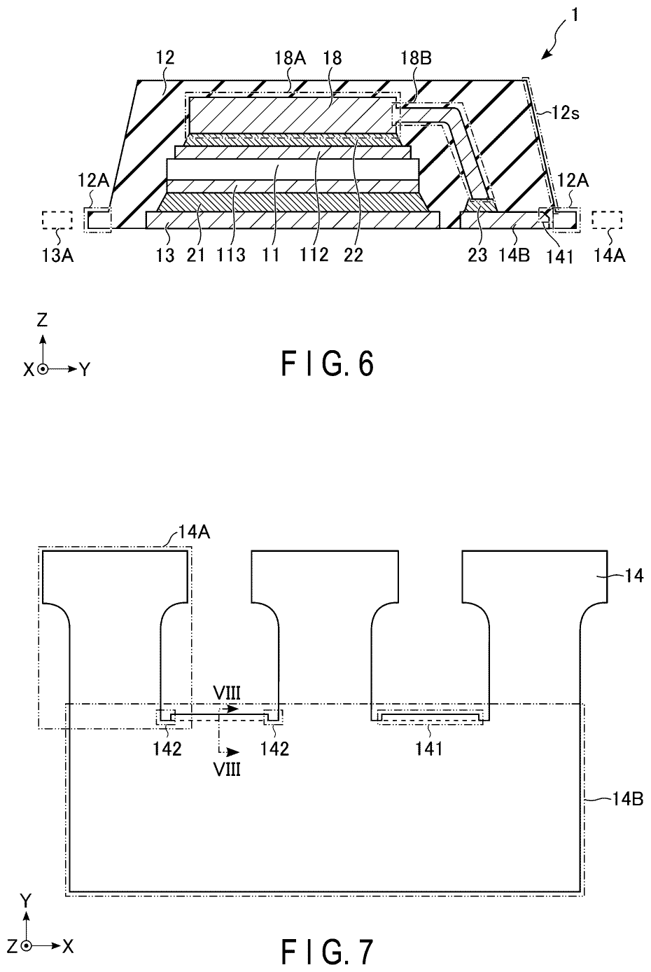

FIG. 6 illustrates a cross-sectional structure of the semiconductor device of the first embodiment. FIG. 6 illustrates a cross section taken along line VI-VI in FIGS. 2 and 3. As illustrated in FIG. 6, the package 12 includes a plurality of protruding portions 12A (only one is illustrated in FIG. 6). The protruding portion 12A protrudes in a direction away from the center of the package 12 in the xy plane. In other words, the protruding portion 12A protrudes in a direction farther away from the center of the semiconductor device 1 than the side surface 12s of the package 12, which is positioned at a level corresponding to the level of the first plate portion 18A or the second plate portion 18B of the conductor 18. In this case, the protruding portion 12A protrudes in the Y direction from the resin 12, which is positioned below the side surface 12s positioned at the level corresponding to the level of the first plate portion 18A or the second plate portion 18B of the conductor 18 and positioned closer to the center of the semiconductor device 1 than the side surface 12s. The protruding portion 12A is positioned in a region including the lower surface of the package 12. Some of the protruding portions 12A are positioned in a region including an end on the Y direction side of the package 12 and positioned between the adjacent first portions (or external terminals) 14A. Other some of the protruding portions 12A are positioned in a region including an end on the-Y direction side and positioned between the adjacent first portions 13A. The upper surface of the protruding portion 12A is aligned with the upper surfaces of the lead frames 13 and 14.

The second portion 14B of the lead frame 14 has an inclined portion (or inclination) 141. The inclined portion 141 extends between an end (or side) of the second portion 14B on the Z direction side and an end (or side) of the second portion 14B on the Y direction side. The inclined portion 141 is inclined with respect to the xz plane or the xy plane, and extends along a straight line connecting the y axis and the z axis. The coordinate on the z axis (or z axis coordinate) of an end of the inclined portion 141 on the-Y direction side is larger than the z axis coordinate of an end of the inclined portion 141 on the Y direction side. That is, the z axis coordinate of each of the inclined portions 141 gradually decreases in the Y direction.

FIG. 7 illustrates a partial structure of the semiconductor device of the first embodiment along an xy plane. FIG. 7 illustrates the lead frame 14.

As illustrated in FIG. 7, each of the inclined portions 141 is positioned between adjacent first portions 14A. Each of the inclined portions 141 occupies a region including an end of the second portion 14B on the Y direction side between the adjacent first portions 14A. Each of the inclined portions 141 occupies a region of the lead frame 14 including a boundary between a region between adjacent first portions 14A and a second portion 14B of the lead frame 14. Each of the inclined portions 141 extends in the Y direction.

Each of the inclined portions 141 occupies a region including a center between an end (that is, a right end) on the X direction side of one first portion 14A positioned farther in the −X direction (that is, the left-hand first portion 14A) and an end (that is, a left end) on the −X direction side of one first portion 14A positioned farther in the X direction (that is, the right-hand first portion 14A). The inclined portion 141 has a non-inclined portion 142 between the right end of the left-hand first portion 14A and the inclined portion, and has a non-inclined portion 142 between the left end of the right-hand first portion 14A and the inclined portion. The non-inclined portion 142 is aligned with the inclined portion 141 in the X direction. The non-inclined portion 142 extends along the xy plane as in a region other than the inclined portion 141 of the lead frame 14. The non-inclined portion 142 is provided to prevent the inclined portion 141 from unintentionally reaching the first portion 14A due to tolerance of a mold in forming the inclined portion 141 and/or formation accuracy. However, one or both non-inclined portions 142 may not be provided, and the inclined portion 141 may reach the left first portion 14A and/or the right first portion 14A. The non-inclined portions 142 does not have an inclined portion, such as the inclined portion 141, and has a surface perpendicular to the upper surface of the lead frame 14 or is perpendicular to the upper surface of the lead frame 14 in one example.

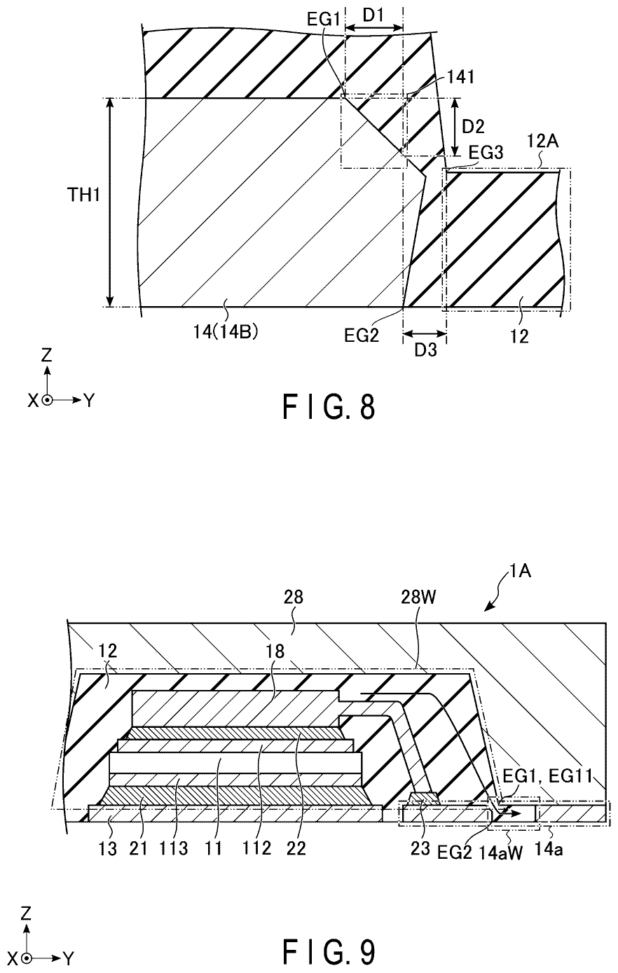

FIG. 8 illustrates a cross-sectional structure of the semiconductor device of the first embodiment. FIG. 8 illustrates a cross section taken along line VII-VII of FIG. 7.

As illustrated in FIG. 8, the inclined portion 141 extends at least over a length D1 along the Y direction, in other words, has at least a dimension D1 along the Y direction. The length D1 is equal to the interval between the side (upper right side) or the end EG1 on the side in the Y direction of the surface (upper surface) on the side in the Z direction of the lead frame 14 and an imaginary line (or coordinates on the y axis of the lower right side EG2) extending along the z axis from the side (lower right side) or the end EG2 on the side in the Y direction of the surface (lower surface) on the side in the −Z direction of the lead frame 14. That is, the inclined portion 141 extends over the coordinate on the y axis of the upper right side EG1 and the coordinate on the y axis of the lower right side EG2. The plate portion 14B including the inclined portion 141 is covered with the resin 12 and the protruding portion 12A.

The side (right side) on the Y direction side of the lead frame 14 may have an inclined surface due to the limitation of the technique of forming the lead frame 14. FIG. 8 illustrates such an example. In this case, the inclined portion 141 may extend, in the Y direction, from the upper right side EG1 beyond a position on an imaginary line (or coordinates on the y axis of the lower right side EG2) extending from the lower right side EG2 along the z axis.

The inclined portion 141 extends at least over a length D2 along the Z direction, in other words, has at least a dimension D2 along the Z direction. That is, the inclined portion 141 extends, in the Z direction, from the upper right side EG1 and a position on an imaginary line extending from the lower right side EG2 along the z axis. In a case where the right side of the lead frame 14 has an inclined surface, the inclined portion 141 may extend, in the Z direction, from the upper right side EG1 beyond a position on an imaginary line extending from the lower right side EG2 along the z axis. In one example, the length D2 is substantially the same as the length D1. In the specification and claims, two elements that are “substantially the same” and “substantially equal” mean that the two elements are intended to be the same but are not completely the same based on the limitations of manufacturing and measurement techniques.

The lower right side EG2 has a distance D3 in the X direction from a connection surface (or a connection end) EG3. The connection surface EG3 is a surface on the −Y direction side of the protruding portion 12A of the package 12, and is a boundary between a portion other than the protruding portion 12A of the package 12 and the protruding portion 12A. The connection surface EG3 extends along the xz plane.

The second portion 14B has a thickness (that is, a dimension in the Z direction) TH1. The thickness TH1 is an average value, a maximum value, or a minimum value of the thicknesses of the second portion 14B.

The distance D3 is substantially equal to 0.5 to 2 times the length D1 or/and the length D2. In one example, the distance D3 is substantially equal to a size of equal to or greater than 0.05 mm and equal to or less than 0.20 mm. In one example, the length D1 is substantially equal to 0.1 mm. In one example, the length D2 is less than or equal to half of the thickness TH1.

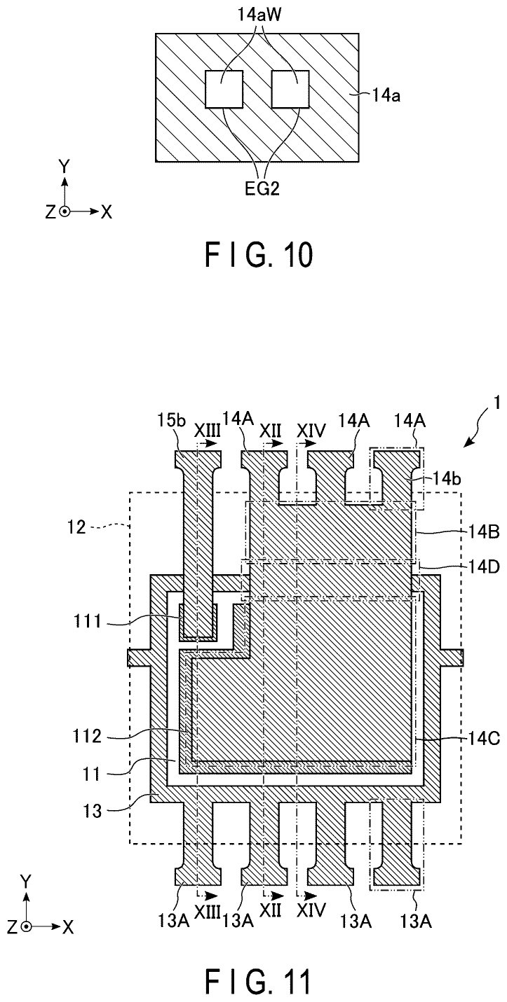

FIG. 9 illustrates one state during manufacturing of the semiconductor device of the first embodiment. FIG. 9 illustrates the same region as that illustrated in FIG. 6. In the state illustrated in FIG. 9, the structure 1A in the middle of manufacturing the semiconductor device 1 includes a lead frame 14a instead of the lead frame 14. The lead frame 14a is a conductor to be formed into the lead frame 14 in a later step. In the state illustrated in FIG. 9, the lead frame 14a has a structure illustrated in FIG. 10. FIG. 10 illustrates a state during manufacturing of a part of the semiconductor device of the first embodiment. FIG. 10 illustrates the lead frame 14a along the xy plane. As illustrated in FIG. 10, the lead frame 14a has a quadrilateral shape. The lead frame 14a has openings 14aW. The opening 14aW has a quadrilateral shape and penetrates the lead frame 14a. The opening 14aW is positioned in a region between regions to be the first portions 14A. An end (lower end) of the lead frame 14a on the −Y direction side substantially coincides with the lower right side EG2. The lead frame 14a already has the inclined portion 141 at the lower end of the opening 14aW. The first portion 14A is not yet formed.

Referring back to FIG. 9, at the start of the process illustrated in FIG. 9, the structure 1A does not yet have the package 12. With the start of the process illustrated in FIG. 9, the mold 28 is disposed on the upper surface of the structure 1A. The mold has a space 28W therein, and the space 28W has a shape substantially equal to the outer shape of the package 12. Therefore, the side EG11 on the −Z direction side of the space 28W substantially coincides with the connection surface EG3 of the package 12 to be formed. Therefore, the distance between the side EG11 and the imaginary line (or coordinates on the y axis of the lower right side EG2) extending from the lower right side EG2 along the z axis is substantially equal to the distance D3.

Next, a material (that is, resin) of the package (resin) 12 is injected into the space 28W. As a result, the space 28W is filled with the material. During injection, a portion of the material flows in the direction indicated by the arrow. That is, the material flows from the center of the structure 1A toward the Y direction and flows toward the opening 14aW. The flow of the material to the opening 14aW is along the inclined portion 141 of the lead frame 14. The material fills the opening 14aW. Thereafter, the lead frame 14a is formed into the lead frame 14.

According to the first embodiment, a semiconductor device in which chipping of a package is suppressed is provided as described below.

Reference semiconductor devices for comparison as described below are conceivable. That is, the reference semiconductor device does not include the inclined portion 141 in the lead frame 14. Therefore, in the process described above with reference to FIG. 9, the space between the side EG11 of the space 28W of the mold 28 and the lead frame 14 is narrow. Therefore, the flow path of the resin is narrow between the side EG11 and the lead frame 14, and it is difficult for the resin to flow. As a result, a sufficient amount of the resin does not reach the opening 14aW, and the space remains without being filled with the resin in the farther portion of the opening 14aW, that is, a portion on the Y direction side. The semiconductor device completed with this space has a portion of the package 12 where the space is formed as chipping of the package 12. This adversely affects the appearance of the semiconductor device and affects the durability and/or reliability of the semiconductor device.

According to the first embodiment, the lead frame 14 includes the inclined portion 141. Therefore, in the process described above with reference to FIG. 9, the distance between the side EG11 of the space 28W of the mold 28 and the lead frame 14 is wide. Therefore, the flow of the resin of the material of the package 12 is hardly inhibited in the region between the side EG11 and the lead frame 14, and the resin reaches the farther portion of the opening 14aW and can fill the opening 14aW. Therefore, the chipping of the package 12 is suppressed.

The above description relates to an example in which the source electrode 112 is exposed on the upper surface and the drain electrode 113 is exposed on the lower surface of the semiconductor chip 11. However, the first embodiment is not limited to this example, and the gate electrode 111, the source electrode 112, and the drain electrode 113 may be arranged in any manner.

The lead frame 14 may be integrated with the conductor 18, and the lead frame 15 may be integrated with the conductor 17. FIG. 11 illustrates such an example, and illustrates an internal structure of a semiconductor device according to a modification of the first embodiment along the xy plane. As illustrated in FIG. 11, a semiconductor device 1 according to a modification includes lead frames 14b and 15b.

The lead frame 15b overlaps the gate electrode 111 on the −Y direction side. The lead frame 14b includes a third portion 14C and a fourth portion 14D in addition to the first portion 14A and the second portion 14B. The third portion 14C has a shape along the xy plane of the source electrode 112 and overlaps the source electrode 112. The fourth portion 14D is positioned between the second portion 14B and the third portion 14C, and connects the second portion 14B and the third portion 14C. That is, the first portion 14A, the second portion 14B, the third portion 14C, and the fourth portion 14D are continuous.

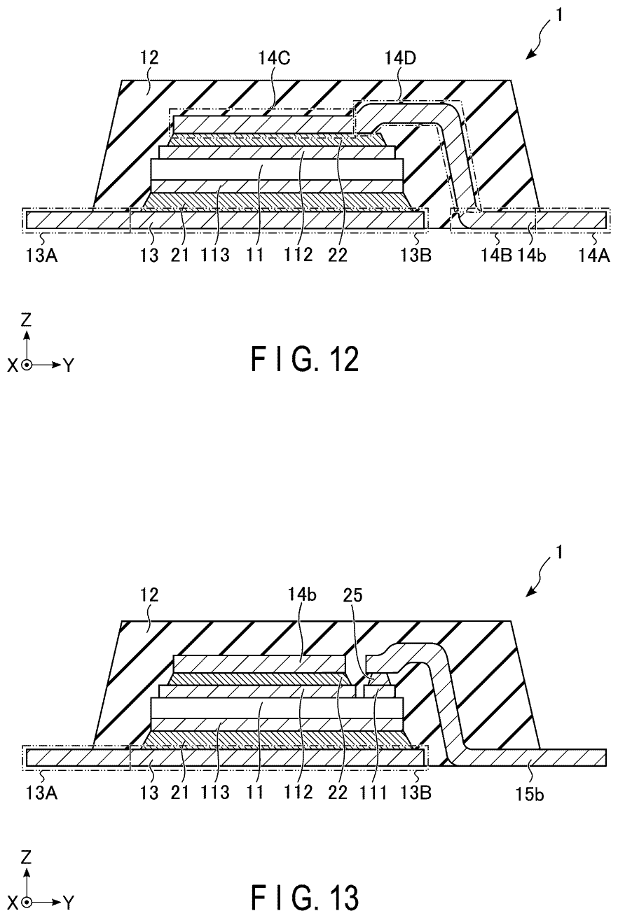

FIG. 12 illustrates a cross-sectional structure of a semiconductor device according to a modification of the first embodiment. FIG. 12 illustrates a cross section taken along line XII-XII in FIG. 11. As illustrated in FIG. 12, the third portion 14C is positioned farther in the Z direction than the semiconductor chip 11. The third portion 14C is in contact with the bonding layer 22 on a lower surface.

The fourth portion 14D is connected to a right end of the third portion 14C at a left end. In one example, the fourth portion 14D is positioned farther in the Z direction than the third portion 14C. A right end of the fourth portion 14D is positioned farther in the-Z direction than a left end of the fourth portion 14D. That is, the fourth portion 14D has a portion extending along the Z direction between the left end and the right end. The fourth portion 14D is connected to the left end of the second portion 14B at the right end.

FIG. 13 illustrates a cross-sectional structure of a semiconductor device according to a modification of the first embodiment. FIG. 13 illustrates a cross section taken along line XIII-XIII of FIG. 11. As illustrated in FIG. 13, the lead frame 15b is positioned farther in the Z direction than the semiconductor chip 11 in a portion including a left end. The lead frame 15b is in contact with the bonding layer 25 on a lower surface at the left end. The lead frame 15b is aligned with the lead frame 13 in a portion including a right end and exposed from the package 12. The portion including the left end of the lead frame 15b and the portion including the right end of the lead frame 15b are connected to each other by an intermediate portion. The intermediate portion extends along the z axis.

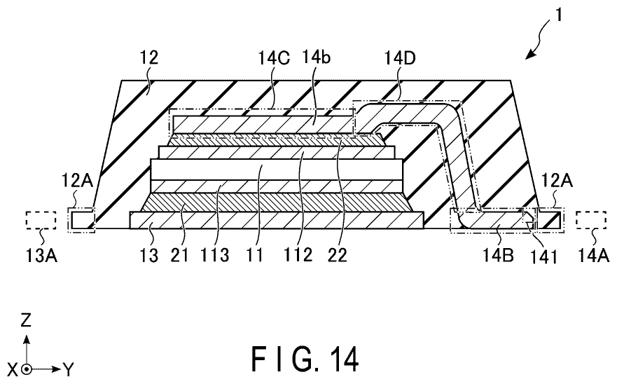

FIG. 14 illustrates a cross-sectional structure of a semiconductor device according to a modification of the first embodiment. FIG. 14 illustrates a cross section taken along line XIV-XIV in FIG. 11. As illustrated in FIG. 14, the second portion 14B has an inclined portion 141.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first lead frame;
a semiconductor chip including a first electrode provided farther in a first direction than the first lead frame and electrically coupled to the first lead frame, and a second electrode;
a first conductor electrically coupled to the second electrode;
a second lead frame aligned with the first lead frame at a position farther in a second direction than the first lead frame and including a first terminal and a plate portion connected to the first terminal, the plate portion being electrically coupled to the first conductor and having an inclination over a first surface on a side in the first direction and a side surface on a side in the second direction; and
a resin that covers a part of the first lead frame, the semiconductor chip, the first conductor, the plate portion of the second lead frame, and a part of the first terminal of the second lead frame.

2. The semiconductor device according to claim 1, wherein
the second lead frame further includes a second terminal connected to the plate portion,
the second terminal is aligned with the first terminal in a third direction, and
the inclination is positioned between the first terminal and the second terminal.

3. The semiconductor device according to claim 2, wherein
the inclination extends in the third direction.

4. The semiconductor device according to claim 1, wherein
the resin covers the semiconductor chip, the first conductor, and the plate portion of the second lead frame, and has a second surface on a side of the first direction,
a first portion of the resin is aligned with the plate portion at a position farther in the second direction than the plate portion, and has a third surface on a side of the first direction, and
the second surface is positioned farther in the first direction than the third surface.

5. The semiconductor device according to claim 4, wherein
the plate portion has a fourth surface at a side in a direction opposite to the first direction, and
a distance along the second direction between an end of the first portion on a side in a direction opposite to the second direction and an end of the fourth surface on a side of the second direction is 0.05 mm or more and 0.2 mm or less.

6. The semiconductor device according to claim 4, wherein
the plate portion has a first dimension in the first direction, and
a second dimension along the first direction from the first surface of the inclination is equal to or less than half of the first dimension.

7. The semiconductor device according to claim 1, wherein
the first conductor and the second lead frame are continuous.

8. The semiconductor device according to claim 1, wherein
the second lead frame has a second side surface and a third side surface between the first terminal and the second terminal, and
the first surface is positioned between the second side surface and the third side surface, and protrudes in the second direction with respect to the second side surface and the third side surface.

9. A semiconductor device comprising:
a first lead frame;
a semiconductor chip including a first electrode provided farther in a first direction than the first lead frame and electrically coupled to the first lead frame, and a second electrode;
a connector electrically coupled to the second electrode;
a second lead frame including a first terminal, a second terminal aligned with the first terminal in a second direction perpendicular to the first direction, and a plate portion connected to the first terminal and the second terminal and inclined at an end of a first surface between the first terminal and the second terminal; and
a resin covering a part of the first lead frame, the semiconductor chip, the connector, the plate portion of the second lead frame, and a part of the first terminal of the second lead frame.

10. The semiconductor device according to claim 9, wherein
the first lead frame is aligned with the second lead frame in a third direction intersecting the first direction and the second direction.

11. The semiconductor device according to claim 9, wherein
the inclination extends in the second direction.

12. The semiconductor device according to claim 9, wherein
the resin covers the semiconductor chip, the connector, and the plate portion of the second lead frame, and has a second surface on a side of the first direction,
a first portion of the resin is aligned with the plate portion at a position farther in a third direction than the plate portion, and has a third surface on a side of the first direction, and
the second surface is positioned farther in the first direction than the third surface.

13. The semiconductor device according to claim 12, wherein
the plate portion has a fourth surface at a side in a direction opposite to the first direction, and
a distance along the third direction between an end of the first portion on a side in a direction opposite to the third direction and an end of the fourth surface on a side of the third direction is 0.05 mm or more and 0.2 mm or less.

14. The semiconductor device according to claim 12, wherein
the plate portion has a first dimension in the first direction, and
a second dimension along the first direction from the first surface of the inclination is equal to or less than half of the first dimension.

15. The semiconductor device according to claim 9, wherein
the first conductor and the second lead frame are continuous.

16. The semiconductor device according to claim 1, wherein
the second lead frame has a first side surface including the inclination, and a second side surface and a third side surface between the first terminal and the second terminal, and
the first surface is positioned between the second side surface and the third side surface, and protrudes in a third direction intersecting the first direction and the second direction with respect to the second side surface and the third side surface.
